(19) United States
(12) Patent Application Publication
(10) Pub. No.: US 2006/0223292 A1
(43) Pub. Date: Oct. 5, 2006

(54) Method of manufacturing semiconductor device

(75) Inventors: Kensuke Okonogi, Tokyo (JP); Kiyonori Oyu, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/390,138

(22) Filed: Mar. 28, 2006

(30) Foreign Application Priority Data
Mar. 29, 2005 (JP) 2005-094446

(51) Int. Cl. H01L 21/425

(52) U.S. Cl. 438/530

(57) ABSTRACT

In a method of manufacturing a semiconductor device with a MOS transistor, a channel impurity doped layer of a first conductive type is formed in a silicon substrate. First material is implanted into regions for diffusion layers of a second conductive type as sources/drains of the MOS transistor in the channel impurity doped layer. Heat treatment is carried out after the implanting process of the first material. Then, the diffusion layers are formed in the silicon substrate after the carrying out heat treatment.

### BACKGROUND OF THE INVENTION

1. Field of the Invention

The present invention generally relates to a method of manufacturing a semiconductor device having MOS transistors.

2. Description of the Related Art

The existence of point defects such as vacancies and interstitial silicon atoms in silicon crystal is known. It is known that a large number of interstitial silicon atoms are generated due to irradiation damages when impurity ions are implanted as one of manufacturing steps for a semiconductor device.

A DRAM as a conventional semiconductor device and manufacturing methods thereof are disclosed in Japanese Laid Open Patent Publication (JP-P2003-17586A), and Japanese Patent No. 3212150.

FIG. 1 is a sectional view showing a structure of a conventional DRAM 100. In this conventional DRAM 100, two cell transistors sharing a bit line 130 are formed in a single active region. The active region is surrounded by a shallow trench isolation (STI) 110 which is embedded in a semiconductor substrate. Also, a P-type well layer 102 is formed in the substrate, and a P-channel impurity doped layer 103 is formed in this P-type well layer 102. At least, a substrate potential is applied to the P-type well layer 102, and the P-type channel impurity doped layer 103 determines threshold voltages of the transistors. Also, N-type (low concentration) diffusion layers 104 are formed as drains or sources in the vicinity of the surface of the substrate. Also, a buried layer 109 is formed under the N-type diffusion layer 104. The buried layer 109 is formed to weaken an electric field, as described in the above-described Japanese Patent No. 3212150. It should be noted that an N-type buried well layer (not shown) may be formed under the P-type well layer 102.

A gate insulating film 111 is formed on the substrate, and gate electrodes 120 are formed on the gate insulating film 111. The gate electrode 120 is formed of a phosphorus doped polysilicon film and a tungsten silicide film. A thermal oxide film 122 is formed on each of side surfaces of the gate electrode 120 in order to improve a breakdown voltage of the gate insulating film 111. Also, a side spacer 123 is formed on each of side portions of the gate electrode 120. An insulating film 132 is formed on the gate electrode 120 to cover it. The insulating film 132 is made of a silicon nitride film or the like, which is used to process the gate electrodes 120. An interlayer insulating film 133 is formed on the insulating film 132. Plugs 131 are formed to penetrate the gate insulating film 111, the silicon nitride film 132, and the interlayer insulating film 133. One of the plugs 131 is used to connect the bit line 130 with an N-type diffusion layer 104. The other plugs 131 are used to connect the other N-type diffusion layers 104 to the plugs 143. The plugs 143 are connected to capacitors 150. Also, an interlayer insulating film 141 is connected between the bit line 130 and the plugs 143. Furthermore, an interlayer insulating film 142 is formed between the bit line 130 and the capacitors 150.

Referring now to the above JP-P2003-17586A, a method for manufacturing the DRAM 100 shown in FIG. 1 will be described as follows. That is, firstly, the STI (shallow Trench Isolation) 110 is formed in the substrate, and the active region is formed which is surrounded by the STI 110. Subsequently, in order to form the P-type well layer 102 to which the substrate potential is applied, ion implantation is carried out plural times by using P-type impurity (boron). At this time, ion implantation energy and an ion implant dose are 300 KeV and 1×10¹³ cm⁻², 150 KeV and 5×10¹² cm⁻², 50 KeV and 1×10¹² cm⁻², 10 KeV and 2×10¹² cm⁻², respectively. Thereafter, in order to diffuse the impurity, thermal treatment is carried out at 1000° C. for 10 minutes. Subsequently, the P-type impurity (boron) is implanted to adjust the threshold voltage, so that the P-type channel impurity doped layer 103 is formed. At this time, ion implantation energy and an ion implant dose are 10 KeV and 8×10¹² cm⁻². Thus, a P-type layer of the high concentration of about 1×10¹³ cm⁻³ is present in a channel region between an oxide film and the silicon substrate surface in a transistor to be manufactured. Next, a film for the gate insulating film 111 and a film of the gate electrodes 120 are deposited over an entire surface of the substrate. Thereafter, the gate electrodes 120 are formed at desirable positions by a lithography technique and a dry etching technique. Subsequence, thermal treatment is carried out to side surfaces of each of the gate electrodes 120 and the surface of the substrate. Next, in order to form the N-type diffusion layers 104 having a low concentration, phosphorus is implanted in the substrate. At this time, implantation energy and an implant dose of phosphorus are 10 Kev and 2×10¹³ cm⁻². Thermal treatment after phosphorus implantation may be carried out in common to thermal treatment for peripheral transistors. However, the thermal treatment may be carried out just after phosphorus implantation. The thermal treatment is carried out for several tens of seconds in a nitrogen atmosphere in the temperature range of 900 to 1000° C. Description of the succeeding manufacturing steps is omitted.

When a design rule is made further finer in DRAM, it is strongly required to suppress channel leakage current when a cell transistor is turned OFF. In order to maintain a higher threshold voltage, an amount (concentration) of the impurity (boron) used to form the channel impurity doped layer 103 must be increased. For example, in the above-described manufacturing method, the implant dose of boron is as many as approximately 1×10¹³ cm⁻². When the boron concentration of the channel impurity doped layer 103 is high, the implant dose of the impurity (phosphorus) used to form the N-type diffusion layers 104 must also be increased. When the cell transistors are furthermore made finer, a larger implant dose of phosphorus is necessarily required.

When the implant dose of phosphorus to form source/drain is increased, the point defects (interstitial silicon atoms and vacancies) are increased when the phosphorus is implanted. When there are many interstitial silicon atoms and vacancies, many “vacancy defects” are left after the thermal treatment. The reason why the “vacancy defects” are increased is as follows. That is, the interstitial silicon atoms are immediately diffused to disappear from the phosphorus implanted layer through the thermal treatment, while the vacancies of slow diffusion speed are left in this phosphorus implanted layer. As shown in FIG. 2, it is known that the vacancy defects left in the N-type diffusion layer 104 have dangling bonds, as described in “Defects related to DRAM leakage current studied by electrically detected magnetic resonance” (Physica B, volume 308-310, pages 1169 to 1172 in 2001), by T. Umeda et. al. A trap level is formed in a band gap by the dangling band. If the trap level is present in the band gap, a junction leakage current flows through this level. In other words, the increase of the vacancy defects may cause the junction leakage current in the PN junction between the channel impurity doped layer 103 and the N-type diffusion layer 104.

As previously described, when the implant dose of boron is increased so as to maintain the high threshold voltage, the implant dose of phosphorus is also increased. Thus, the vacancy defects are increased. As a result, the junction leakage current caused by the vacancy defects is increased. More specifically, in DRAM, electron charges are stored in a capacitor in order to hold data. As a consequence, increase of junction leakage current may causes leakages of electron charges from the capacitor, resulting in deterioration in a data holding characteristic of the DRAM.

### SUMMARY OF THE INVENTION

An object of the present invention is to provide a method of manufacturing a semiconductor device, in which vacancy defects in the semiconductor device can be reduced.

Another object of the present invention is to provide a method of manufacturing a semiconductor device, in which a junction leakage current can be reduced.

A further object of the present invention is to provide a method of manufacturing a DRAM, in which a data holding characteristic can be improved.

A still further object of the present invention is to provide a method of manufacturing a DRAM, in which power consumption can be reduced.

In an aspect of the present invention, a method of manufacturing a semiconductor device with a MOS transistor, is achieved by forming a channel impurity doped layer of a first conductive type in a silicon substrate; by implanting first material into regions for diffusion layers of a second conductive type as sources/drains of the MOS transistor in the channel impurity doped layer; by carrying out heat treatment after the implanting process of the first material; and by forming the diffusion layers in the silicon substrate after the carrying out heat treatment.

Here, the first material may be silicon, or an element of IV A group. Especially, the first material may be nitrogen.

Also, an implanting energy of the first material is determined such that a range of the first material is smaller than a depth of the diffusion layers from a surface of the silicon substrate. Also, an implant dose of the first material may be equal to or more than 1×10¹³ cm⁻² and less than or equal to 1×10¹⁴ cm⁻².

Also, the carrying out heat treatment is achieved by carrying out the heat treatment in a range of 800° C. to 1100° C.

Also, the method may be achieved by further forming a gate electrode of the MOS transistor through a gate insulating film on the silicon substrate; and carrying out a thermal oxidizing process after the forming a gate electrode. The forming a gate electrode and the carrying out a thermal oxidizing process are executed between the forming a channel impurity doped layer and the implanting first material.

Also, the method may be achieved by further forming a gate electrode of the MOS transistor through a gate insulating film on the silicon substrate. The forming a gate electrode is executed between the forming a channel impurity doped layer and the implanting first material. The carrying out heat treatment is achieved by carrying out a thermal oxidizing process.

Also, the method may be achieved by further forming a capacitor connected with one of the diffusion layers.

### BRIEF DESCRIPTION OF THE DRAWINGS

FIG. 1 is a sectional view showing the structure of a conventional DRAM;

FIG. 2 is a schematic diagram showing a vacancy defect;

FIG. 3 is a flow chart showing a manufacturing method of a semiconductor device according to the present invention;

FIGS. 4 and 5 are diagrams showing an effect of the semiconductor device according to the present invention;

FIG. 6 is a sectional view showing a structure of a DRAM manufactured according to a first embodiment of the present invention;

FIGS. 7A to 7G are sectional views showing manufacturing steps of the semiconductor device according to the first embodiment of the present invention;

FIG. 8 is a graph showing a relationship between a residual defect amount and an implant dose of phosphorus;

FIG. 9 is a diagram showing an effect achieved according to the first embodiment of the present invention;

FIG. 10 is a graph showing a relationship between a threshold voltage and an implant dose of silicon;

FIG. 11 is a graph showing a relationship between a junction leakage current and an implant dose of silicon;

FIG. 12 is a flow chart showing the manufacturing method of the semiconductor device according to a second embodiment of the present invention;

FIG. 13 is a sectional view showing a manufacturing step of the semiconductor device according to the second embodiment of the present invention; and

FIG. 14 is a diagram showing an effect achieved according to the second embodiment of the present invention.

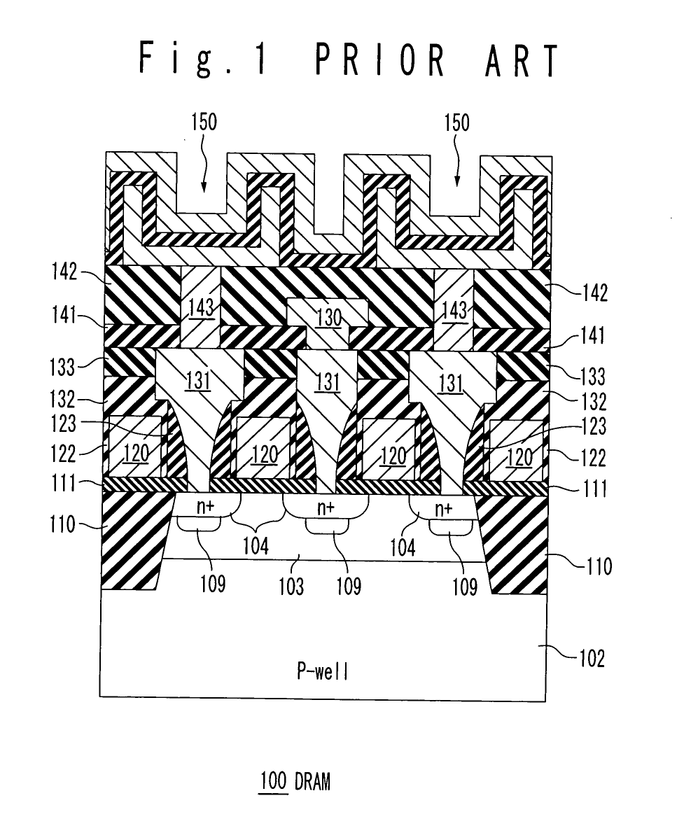

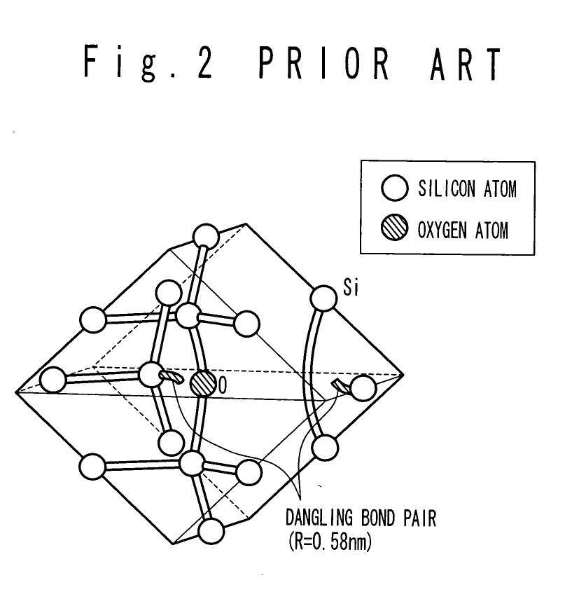

### DESCRIPTION OF THE PREFERRED EMBODIMENTS

Hereinafter, a method of manufacturing a semiconductor device according to the present invention will be described in detail with reference to the attached drawings. In the present invention, the semiconductor device has MOS transistors.

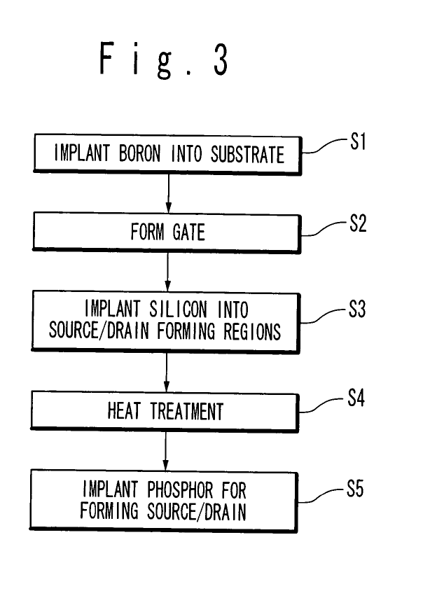

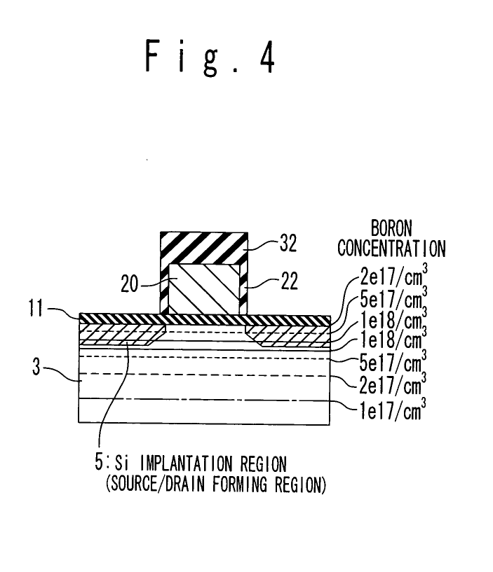

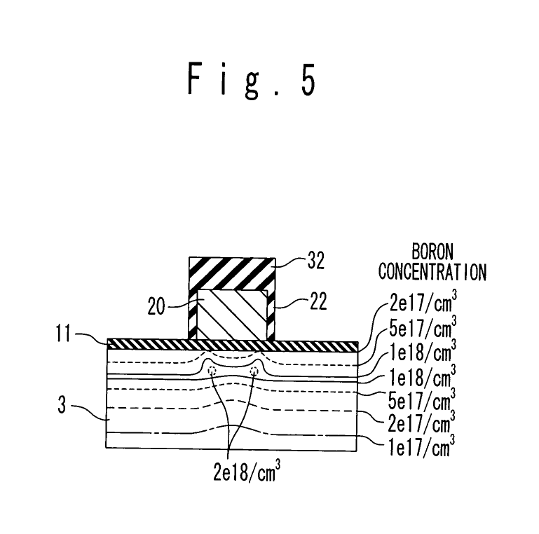

First, the manufacturing method of the semiconductor device according to the present invention will be summarized and effects of this manufacturing method will be described with reference to FIG. 3 to 5. FIG. 3 is a flow chart showing manufacturing steps in the manufacturing method of the semiconductor device according to the present invention. FIGS. 4 and 5 are sectional views showing a manufacturing step of the semiconductor device.

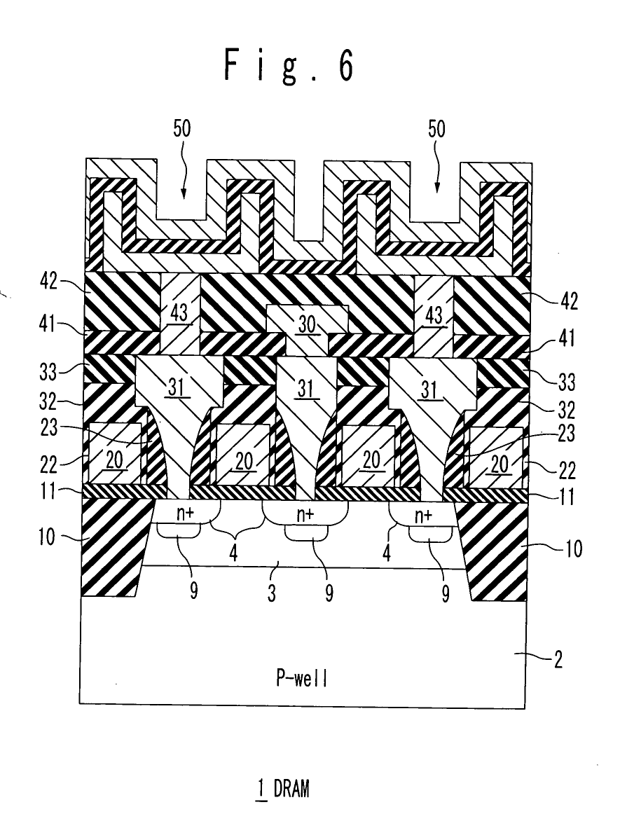

First, a P-type impurity (boron) is implanted into a silicon substrate, so that a channel impurity doped layer 3 is formed (step S1). Subsequently, gate electrodes 20 are formed through a gate insulating film 11 on the channel impurity doped layer 3 (step S2). Side surfaces of the gate electrode 20 may be covered by oxide films 22. As a result, a semiconductor device structure as shown in FIG. 6 is accomplished. Subsequently, as shown in FIG. 3, source/drain forming regions 5 are present in the channel impurity doped layer 3. According to the present invention, silicon is implanted into the source/drain forming regions 5 (step S3) after the gate process is carried out (step S2) and before the source and drain are formed (step S5). Thereafter, thermal treatment is carried out (step S4).

Effects achieved by the silicon implantation and thermal treatment are as follows. That is, first of all, vacancies and interstitial silicon atoms are produced in the source/drain forming regions 5 due to irradiation damage in the silicon implantation (step S3). At this time, it could be considered that the implanted silicon atoms may function as the interstitial silicon atoms. As a result, the number of the interstitial silicon atoms becomes larger than the number of the vacancies. When the thermal treatment is carried out, boron atoms introduced into the source/drain forming region 5 are drawn out from the region 5 due to diffusion of the interstitial silicon atoms. More specifically, since a large number of the interstitial silicon atoms are present through introduction of the silicon atoms, the amount of boron ions diffused outside the source/drain forming region 5 is also increased. In other words, boron ions introduced into the source/drain forming region 5 are redistributed to a peripheral portion of the source/drain forming region 5. As a result, as shown in FIG. 5, the concentration of boron is increased below the edge portions of the gate electrode 20.

That is to say, boron ions implanted into the source/drain forming region 5 are redistributed, and the boron concentration below the gate electrode 20 is increased. As a result, an amount of boron ions to be implanted can be reduced, as compared with that of the conventional manufacturing method. In other words, the threshold voltage of the transistor can be maintained in a smaller amount of boron atoms. In addition, since boron ions are diffused, the boron concentration in the source/drain forming region 5 is lowered, and an amount of impurity (phosphorus) to be implanted to form the source/drain can be reduced, as compared with that of the conventional manufacturing method. Thus, the number of defects (namely, interstitial silicon atoms and vacancies) when phosphorus atoms are implanted at a step S5 can be reduced. Accordingly, the vacancy defects can be reduced after the phosphorus ions are implanted at the step S5. It should also be noted that the thermal treatment (step S4) after the silicon implantation (step S3) is carried out under a condition that a number of the vacancies is larger than a number of the interstitial silicon atoms, and a remaining amount of the vacancy defects is nearly equal to zero.

As described above, according to the method of manufacturing the semiconductor device of the present invention, the vacancy defects left in the substrate can be reduced. As a consequence, the junction leakage current due to the vacancy defects can be reduced. More specifically, when the DRAM is manufactured, the data holding characteristics of memory cells can be improved. Thus, a refresh cycle of the DRAM can be set to be longer. As a result, power consumption of the DRAM can be reduced.

Next, a method of manufacturing a semiconductor device according to the present invention will be described in detail with reference to the attached drawings and by using specific numerical values.

### First Embodiment

The semiconductor device manufactured in accordance with the first embodiment of the present invention is a DRAM (dynamic random access memory) 1. FIG. 6 is a sectional view showing the structure of the DRAM 1 manufactured in this first embodiment. In this DRAM 1, two cell transistors sharing a bit line 30 are formed in a single active region. The active region is surrounded by a shallow trench isolation (STI) 10 buried in the semiconductor substrate (silicon substrate). Also, a P-type well layer 2 is formed in the substrate, and a P-type channel impurity doped layer 3 is formed in the P-type well layer 2. At least, a substrate potential is applied to the P-type well layer 2, and the P-type channel impurity doped layer 3 determines threshold voltages of the transistors. Also, N-type (low concentration) diffusion layers 4 are formed in the vicinity of a surface of the substrate. Also, a buried layer 9 is formed under the N-type diffusion layer 4. The buried layer 9 is formed to weaken an electric field. It should be noted that an N-type buried well layer (not shown) may be formed under the P-type well layer 2.

A gate insulating film 11 is formed on the substrate, and gate electrodes 20 are formed on the gate insulating film 11. The gate electrode 20 is made of a phosphorus doped polysilicon film and a tungsten silicide film. A thermal oxide film 22 is formed on each of side portions of the gate electrode 20 in order to improve a breakdown voltage of the gate insulating film 11. Also, a side spacer 23 is formed on each of the side portions of the gate electrode 20. An insulating film 32 is formed to cover the gate electrodes 20. The insulating film 32 is made of a silicon nitride film, which is used to process the gate electrode 20. An interlayer insulating film 33 is formed on the insulating film 32. Also, plugs 31 are formed to penetrate the gate insulating film 11, the silicon nitride film 32, and the interlayer insulating film 33. One of the plugs 32 is used to connect the bit line 30 with the N-type diffusion layer 4. The other plugs 31 are used to connect the other N-type diffusion layers 4 to the plugs 43. The plugs 43 are connected to capacitors 50. Also, an interlayer insulating film 41 is connected between the bit line 30 and the plugs 43. Furthermore, an interlayer insulating film 42 is formed between the bit line 30 and the capacitors 50.

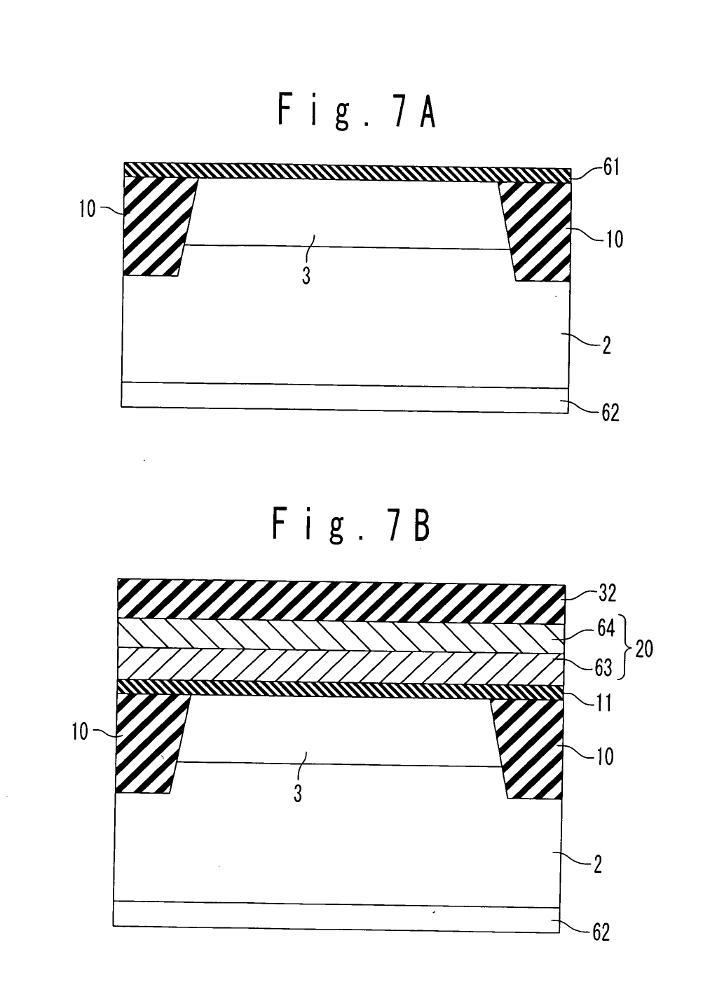

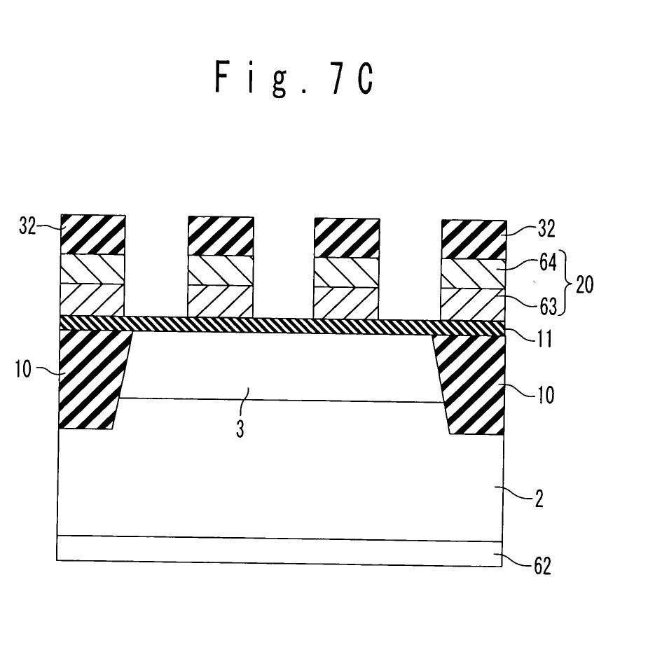

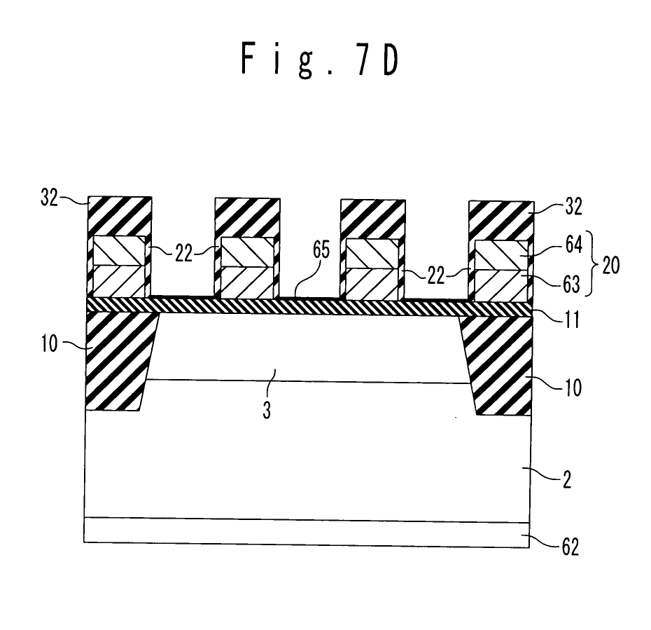

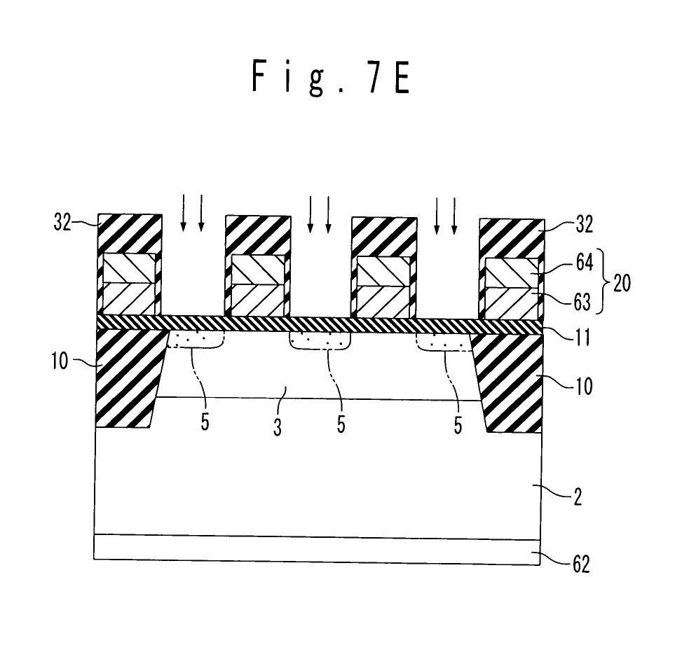

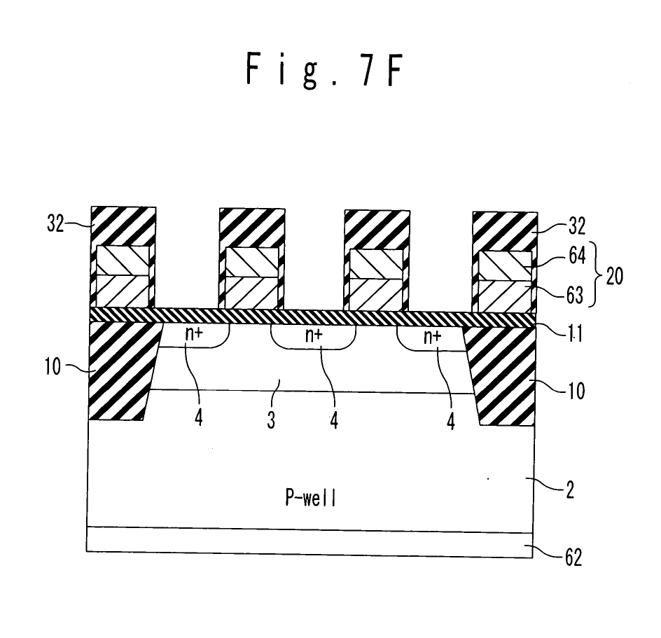

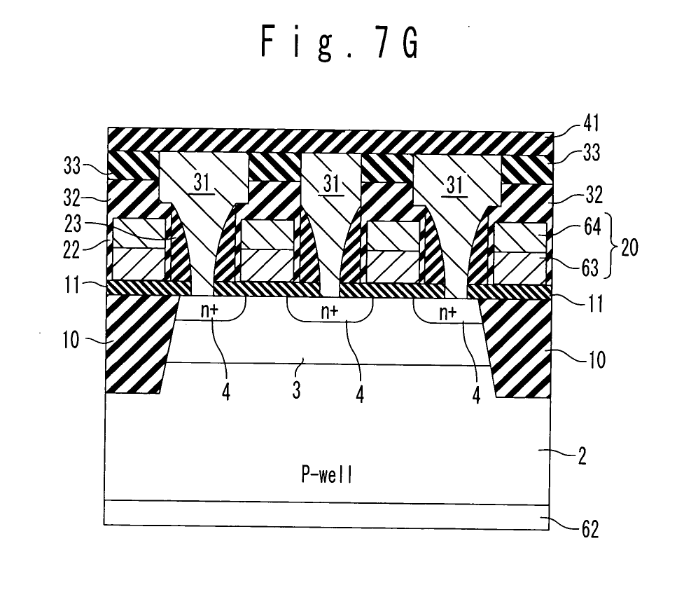

FIG. 7A to 7F show a portion of steps for manufacturing the DRAM 1 shown in FIG. 6.

First, as shown in FIG. 7A, the STI 10 is formed to be embedded in the silicon substrate. Subsequently, a silicon oxide film 61 having the film thickness of 10 nm is formed on an entire surface of the silicon substrate shown in FIG. 7A. Then, an implantation of phosphorus is carried out in order to form an N-type buried well layer 62. Implantation energy and an implant dose of phosphorus are 1000 KeV and 1×10¹³ cm⁻².

Next, in order to form the P-type well layer 2, implantation of boron is carried out 4 times. Implantation energies and implant doses of boron are 300 KeV and 1×10¹³ cm^{-2, 150} KeV and 5×10¹² cm^{-2, 50} KeV and 1×10¹² cm^{-2, 10} KeV and 1×10¹² cm⁻², respectively. Thereafter, thermal treatment is carried out for 30 minutes at the temperature of 1000° C. Subsequently, an implantation of boron is carried out to form the P-type channel impurity doped layer 3. At that time, the implantation energy and an implant dose of boron are 10 KeV and 7×10¹² cm². Thereafter, thermal treatment is carried out for 10 seconds at the temperature of 1000° C. Thus, the P-type well layer 2 and the P-type channel impurity doped layer 3 are formed (step S1 of FIG. 3). It should be noted that an dose of boron to be implanted into the channel region between the oxide film and the silicon surface in the transistor is approximately 0.8×10¹³ cm⁻² in total. The implant dose (0.8×10¹³ cm⁻²) is nearly equal to 80% of the implant dose of 1.0×10¹³ cm⁻² in the conventional manufacturing method.

Next, the silicon oxide film 61 covering the surface of the silicon substrate is removed. Thereafter, as shown in FIG. 7B, a gate insulating film 11 having the film thickness of 7 nm is formed over the entire surface of the silicon substrate by a thermal oxidizing method. Subsequently, a film 20 for gate electrodes 20 is deposited over the entire surface of the silicon substrate. More specifically, a polysilicon film 63 having the film thickness of 70 nm into which phosphorus is doped is formed, and then a tungsten silicide film 64 having the film thickness of 100 nm is formed. Subsequently, an insulating film 32 is formed on the tungsten silicide film 64. The insulating film 32 includes a silicon oxide film having the film thickness of 30 nm, and a silicon nitride film having the film thickness of 150 nm.

Next, a predetermined mask is used, and the insulating film 32, the tungsten silicide film 26, and the polysilicon film 25 are sequentially etched. As a result, as shown in FIG. 7C, the gate electrodes 20 are formed through the gate insulating film 11 on the silicon substrate (FIG. 3 in step S2).

Next, a thermal oxidizing process is carried out. As a result, as shown in FIG. 7D, a silicon oxide film 22 is formed on each of side surfaces of each of the gate electrode 20. The condition of the thermal oxidizing process is set the thickness of the silicon oxide film 22 to be 10 nm on the side surface of the gate electrode 20. Also, another silicon oxide film 65 having the film thickness of 8 nm is formed partially in a region of the surface of the gate insulating film 11 other than the gate electrode 20 through the thermal oxidizing process operation.

According to the first embodiment, after the thermal oxidizing process, the implantation of silicon is carried out (step S3 in FIG. 3). As shown in FIG. 7E, the source/drain forming regions 5 are present in the channel impurity doped layer 3. In this source/drain forming region 5, a source or drain of a MOS transistor will be formed later. The silicon is implanted into the source/drain forming regions (silicon injection region) 5. In this implantation step, implantation energy and an implant dose of silicon atoms are 7 KeV and 2×10¹³ cm⁻². Subsequently, thermal treatment is carried out for 10 seconds in a nitrogen atmosphere at the temperature of 950° C. (step S4 in FIG. 3). As a result, boron ions present in the source/drain forming region 5 are diffused outside the source/drain forming region 5 in connection with the diffusion of interstitial silicon atoms. In other words, boron ions implanted into the source/drain forming regions 5 in the previous step S1 are redistributed to the peripheral region of the source/drain forming regions 5 (refer to FIG. 5). As a result, as shown in FIG. 5, the concentration of boron ions is increased especially below the edge portions of the gate electrode 20.

Next, as shown in FIG. 7F, implantation of phosphorus in the silicon substrate is carried out for N-type low concentration diffusion layers 4 as sources/drains (step S5 in FIG. 3). At this time, implantation energy and an implant dose of phosphorus atoms are 20 KeV and 1.5×10¹³ cm⁻². Then, thermal treatment is carried out for 10 seconds in a nitrogen atmosphere at the temperature of 1000° C. Thus, the N-type low concentration diffusion layers 4 are formed. It should be noted that the amount of implanted phosphorus atoms in the manufacturing method of the present invention is nearly equal to ¾ of the implant dose of 2.0×10¹³ cm⁻³ in the conventional manufacturing method.

Thereafter, a silicon nitride film having the film thickness of 50 nm is deposited, and a silicon oxide film 33 having the film thickness of 300 nm is deposited. Subsequently, a usual flattening method is used to flatten the silicon oxide film 33. Then, as shown in FIG. 7G, the silicon oxide film 33 and the silicon nitride film are sequentially etched, and holes and side spacers 23 are formed in order to form plugs. In this case, a buried layer 9 may be formed under the N-type diffusion layer 4 by implanting phosphorus ions. Next, polysilicon plugs 31 are embedded into the holes. Phosphorus is doped in the polysilicon plugs 31 in high concentration. Subsequently, a silicon oxide film 41 having the film thickness of 100 nm is deposited, and thermal treatment is carried out for 10 seconds at the temperature of 950° C. Then, the DRAM cell as shown in FIG. 6 is manufactured by using the well-known manufacturing method.

According to the manufacturing method in the first embodiment, the implant dose of boron used to form the P-type channel impurity doped layer 3 is nearly equal to 80% of the implant dose in the conventional manufacturing method. The threshold voltage of the cell transistor can be maintained even in the reduced implant dose of boron. This is because boron ions are redistributed through the thermal treatment in the step S4 (refer to FIG. 5). Also, the implant dose of boron is small, and the boron ions are diffused outside the source/drain forming region 5 through the thermal treatment in the step S4. Therefore, it is possible to reduce the amount of phosphorus to be implanted in the step S5. As a result, the number of the defects (namely, interstitial silicon atoms and vacancies) when phosphorus is implanted is decreased, and therefore, the remaining vacancy defects are reduced after the implantation of phosphorous ions.

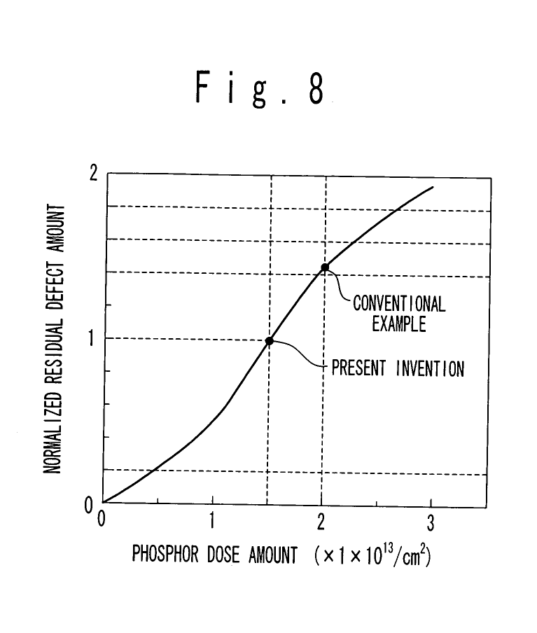

FIG. 8 is a graph showing a relationship between an amount of residual vacancy defects and an implant dose of phosphorus. In FIG. 8, a vertical axis indicates the amount of vacancy defects, and a horizontal axis indicates the implant dose of phosphorus. In the first embodiment, the implant dose of 1.5×10¹³ cm⁻² of phosphorus used to form the N-type diffusion layer 4 is nearly equal to ¾ of the implant dose of 2.0×10¹³ cm⁻² in the conventional manufacturing method. As apparent from FIG. 8, according to the first embodiment, the amount of the vacancy defects left after the implantation of phosphorus is reduced by approximately 30%, as compared with that of the conventional manufacturing method.

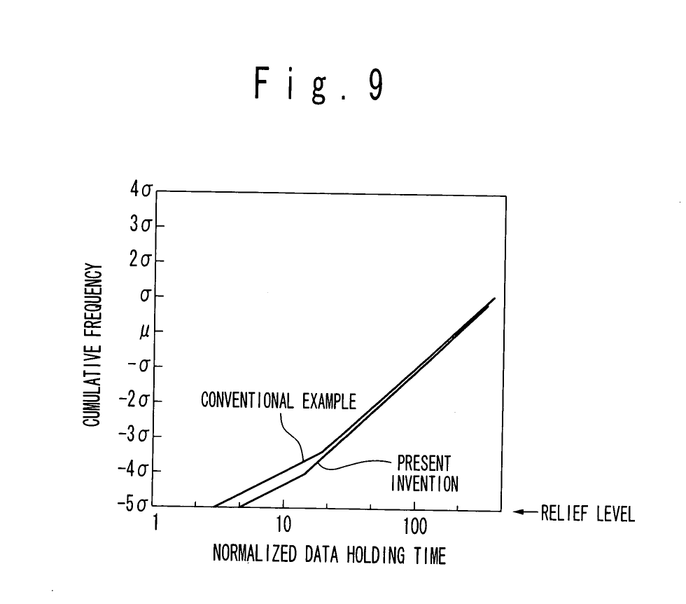

FIG. 9 is a graph showing a result of measuring data holding times with respect to a large number of bits within a single DRAM chip. In FIG. 9, the vertical axis shows a cumulative frequency, and the horizontal axis shows a data holding time. As shown from FIG. 9, according to the first embodiment, the number of bits having a short data holding time is reduced, as compared with that of the conventional manufacturing method. In other words, according to the present invention, the data holding characteristic of the DRAM is improved. This is because the amount of the vacancy defects is reduced, and the junction leakage current due to the vacancy defects is reduced.

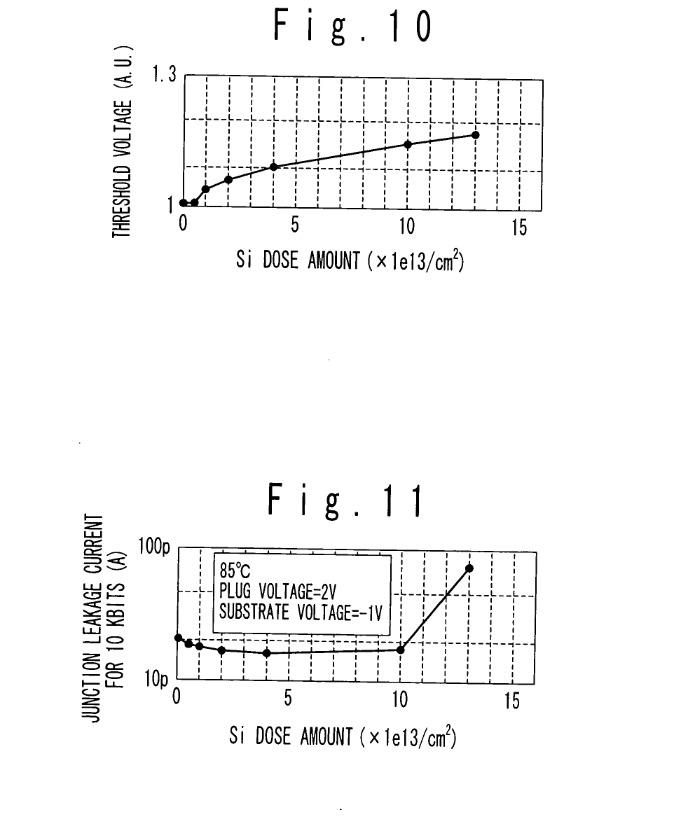

It should be noted that the implant dose and the implantation energy of silicon in the step S3 are not limited only the above-described values. The silicon implantation condition may be determined as follows. That is, FIG. 10 is a graph showing a relationship between a threshold voltage and an implant dose of silicon. As shown in FIG. 10, when the implant dose of silicon is larger than or equal to 1.0×10¹³ cm⁻³, an effect that the threshold voltage is maintained and improved may be achieved. As described above, since silicon is implanted, the number of interstitial silicon atoms becomes larger than the number of vacancies. In the thermal treatment, boron ions are diffused outside the source/drain forming region 5 together with the diffusion of this interstitial silicon atoms. This phenomenon is caused through a diffusion mechanism in which interstitial atoms push out atoms located at lattice positions sequentially. As a result, when the more interstitial silicon atoms are present, the boron ions located at lattice positions are diffused more easily. Therefore, when the implant dose of silicon is more, the threshold voltage is improved more. Specifically, as shown in FIG. 10, it is preferable that the implant dose of silicon is larger than or equal to 1.0×10¹³ cm⁻².

Also, FIG. 11 is a graph showing a relationship between a junction leakage current and an implant dose of silicon. The junction leakage current was measured under the condition that a temperature was 85° C., a plug voltage was 2V, and a substrate voltage is −1 V. As shown in FIG. 11, when an implant dose of silicon is larger than 10×1013 cm⁻² (1.0×10¹⁴ cm⁻²), the junction leakage current increases. This is because the damage caused by the silicon implantation in the step S3 increases the junction leakage current. In other words, the excess silicon implantation deteriorates the effect. As shown in FIG. 11, it is preferable to set the implant dose of silicon to be smaller than or equal to 1.0×10¹⁴ cm⁻². That is to say, according to the present invention, it is preferable to set the implant dose of silicon equal to or larger than 1×10¹³ cm⁻², and smaller than or equal to 1×10¹⁴ cm⁻².

Also, silicon atoms are implanted into a region which is shallower than the region of the N-type diffusion layer formed in the step S5. In other words, the implantation energy of silicon is determined such that a region of silicon from the surface of the silicon substrate becomes shallower than a region of the N-type diffusion layer 4. This is required to avoid that the damage caused through silicon implantation extends out of the N-type diffusion layer 4. If the damage caused through the silicon implantation extends from the N-type diffusion layer 4, the junction leakage current is increased. For instance, a case is assumed, in which an implant dose of phosphorus used to form the N-type diffusion layer 4 is equal to or larger than 1×10¹³ cm⁻², and is smaller than or equal to 1×10¹⁴ cm⁻², and the depth of the N-type diffusion layer 4 after the thermal treatment is approximately 200 nm. In this case, it is preferable that implantation energy of silicon is set a range of silicon to be smaller than a half of the depth of the N-type diffusion layer 4. It should be noted that the range implies an averaged distance by which dopant moves until it completely stops in a substance when the dopant is implanted into the substance.

Also, there is no problem on the thermal treatment temperature at the step S4, if the temperature is defined in a range in which recovery from the damage caused through the silicon implantation and appropriate redistribution of boron ions may be realized. For example, when the thermal treatment temperature is lower than 800° C., there is a possibility that the damage caused through the silicon implantation cannot be sufficiently recovered. Also, if the thermal treatment temperature exceeds 100° C., the amount of redistributed boron ions becomes excessively large, so that there is no merit that the threshold voltage is improved. As a result, according to the present invention, it is suitable when the thermal treatment temperature at the step S4 is set to a temperature range from 800° C. to 1100° C.

In addition, although silicon atoms are implanted in the first embodiment, the similar effect can be achieved even when germanium, carbon, and nitrogen are implanted. Silicon in the substrate has 4 bonds. Therefore, if an element having four bonds is implanted, the element can be introduced into a lattice position without producing any dangling bond. Such an element is referred to as a IV A group element. As the IV A group element, silicon (Si), germanium (Ge), carbon (C), tin (Sn), lead (Pb), and the like are known. However, tin (Sn) and lead (Pb) having large atomic numbers among the above elements may have certain possibility that tin and lead distort silicon crystallinity, so that crystal defects may be generated. Also, since nitrogen (N) has three bonds, one dangling bond is generated in crystal silicon. As a result, when nitrogen is injected, the junction leakage current increases slightly, as compared with the case that silicon is injected. However, even when nitrogen is injected, substantially the same effect as that of the first embodiment may be achieved, as compared with the conventional manufacturing method.

As described above, according to the manufacturing method of the semiconductor device of the present invention, the amount of the vacancy defects left in the substrate can be reduced. As a result, the junction leakage current caused through the vacancy defects can be reduced. Specifically, when the DRAM is manufactured, the data holding characteristic in the memory cells can be improved. If the data holding characteristic of the DRAM is improved, the refresh cycle can be set to be longer. As a result, the power consumption can be reduced. When the manufacturing method of the present invention is applied to a manufacture of a semiconductor device used in a mobile terminal or in a high temperature ambience, the preferable effect may be obtained.

### Second Embodiment

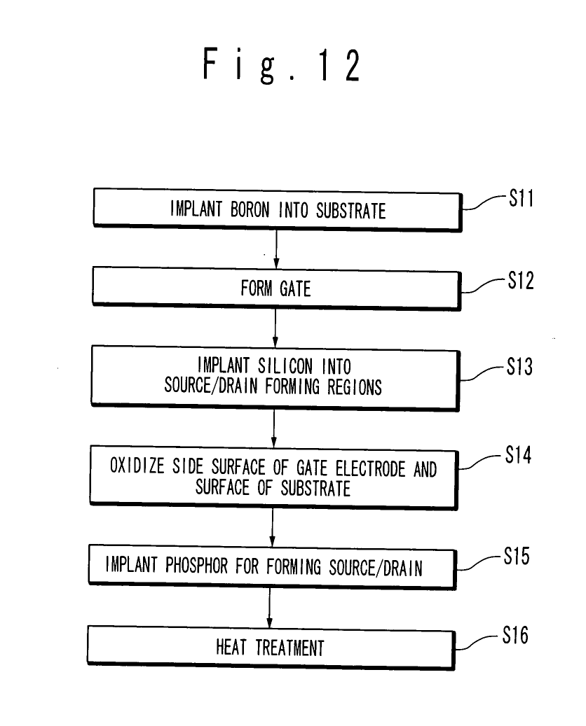

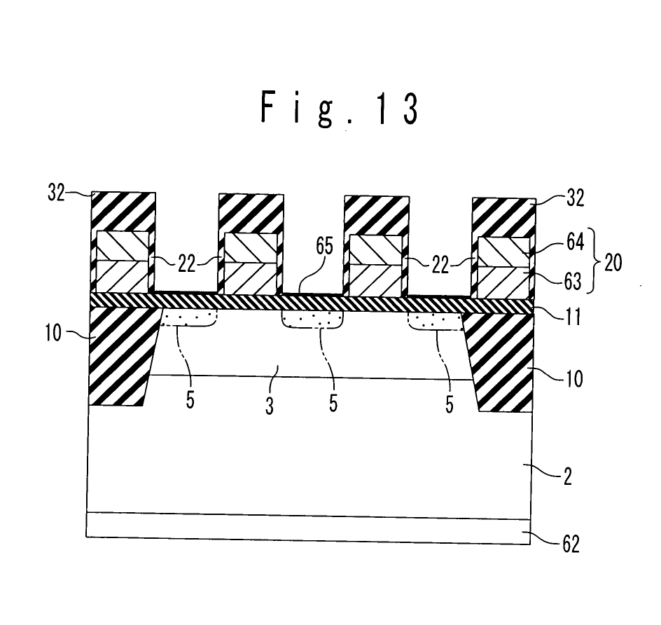

FIG. 12 is a flow chart showing a method of manufacturing a semiconductor device according to the second embodiment of the present invention. In this second embodiment, the description of the steps similar to those of the first embodiment is properly omitted.

Firstly, a P-type impurity (boron) is implanted in a silicon substrate so that the channel impurity doped layer 3 is formed (step S11). Next, the gate electrodes 20 are formed through the gate insulating film 11 on the channel impurity doped layer 3 (step S12). As a result, the structure shown in FIG. 7C is obtained.

In the second embodiment, subsequent to the formation of the gate electrodes, the implantation of silicon is carried out (step S13). In the channel impurity doped layer 3, the source/drain forming regions 5 are present in which the sources or drains in a MOS transistor will be formed later. Silicon is implanted in the source/drain forming region (silicon implantation region) 5. In this implantation step, implantation energy and an implant dose of silicon are 7 KeV and 1×10¹³ cm⁻².

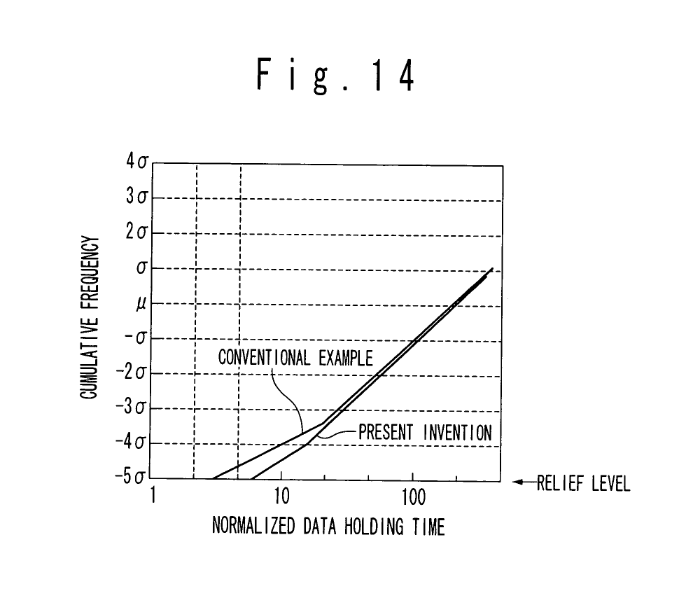

In this second embodiment, the thermal oxidizing process is carried out after the silicon implantation (step S14). As a result, as shown in FIG. 13, a silicon oxide film 22 is formed on each of side surfaces of each of the gate electrodes 20. As The thermal oxidization condition is set such that the thickness of the silicon oxide film 22 is 10 nm on the side surface of the gate electrode 20. Also, through the thermal oxidizing process, the silicon oxide film 65 having the film thickness of 8 nm is formed on a region of the surface of the gate insulating film 11 except for the gate electrode 20.

Also, through this thermal oxidizing process, boron ions in the source/drain forming region 5 are diffused outside this source/drain forming region 5 along with the diffusion of interstitial silicon atoms. In other words, the boron ions implanted into the source/drain forming region 5 in the step S11 are redistributed to a peripheral portion of the source/drain forming region 5 (refer to FIG. 5). As a result, as shown in FIG. 5, concentration of boron becomes high especially below edge portions of the gate electrode 20.

As described above, it should be noted that the silicon oxide film 65 is also formed on the surface of the silicon substrate through the thermal oxidizing process to the side surfaces of each gate electrode 20. In the thermal oxidizing process, a part of boron ions contained in the silicon substrate is diffused in this silicon oxide film 65. In the first embodiment, both the silicon implantation (step S3) and the thermal process (step S4) are carried out after the thermal oxidizing process. Therefore, after a part of boron ions has disappeared from the source/drain forming region 5, the redistribution of boron ions is carried out. On the other hand, in the second embodiment, the thermal oxidizing process (step S14) is carried out after the silicon implantation (step S13). Therefore, the redistribution of boron ions is carried out from a state that boron ions in high concentration are present in the source/drain forming region 5. As a result, the boron ions can be more diffused to the channel region. In other words, an implant dose of boron used to form the channel impurity doped layer 3 in the step S11 can be further reduced.

Next, as shown in the FIG. 7F, the implantation of phosphorus in the silicon substrate is carried out for N-type low concentration diffusion layers 4 as sources/drains (step S15). At this time, implantation energy and an implant dose of phosphorus are 20 KeV and 1.0×10¹³ cm². Then, a thermal process is carried out for 10 seconds in a nitrogen atmosphere at the temperature of 1000° C. (step S16). Thus, the N-type low concentration diffusion layers 4 are formed.

In the second embodiment, the implant dose of phosphorus is nearly equal to ½ of the implant dose (2.0×10¹³ cm⁻²) in the conventional manufacturing method. In other words, in the second embodiment, the implant dose of phosphorus can be further reduced, as compared with that of the conventional manufacturing method. As a result, the number of the defects (namely, interstitial silicon atoms and vacancies) when phosphorus is implanted is furthermore decreased. Therefore, the number of vacancy defects remained after the implantation of phosphorus is further reduced.

FIG. 14 is a diagram showing effects achieved by this second embodiment. Similar to FIG. 9, FIG. 14 is a graph showing a measurement result of data holding times in a large number of bits in a single DRAM chip. In FIG. 14, the vertical axis indicates a cumulative frequency, and the horizontal axis indicates a data holding time. As seen from FIG. 14, in the second embodiment, the number of bits having short data holding times is reduced, as compared with that of the conventional manufacturing method. In other words, according to the present invention, the data holding characteristic of the DRAM can be improved. This is because the amount of the vacancy defects is reduced, and the junction leakage current due to the vacancy defects is reduced.

It should be noted that the implantation condition of silicon and the thermal treatment condition may be set to the same range as that of the first embodiment. Also, instead of silicon, germanium, nitrogen, and carbon may be implanted.

As described above, in the manufacturing method of the semiconductor device of the present invention, the amount of the vacancy defects left in the substrate can be reduced. As a result, the junction leakage current caused due to the vacancy defects can be reduced. More specifically, when the DRAM is manufactured, the data holding characteristics of the memory cells can be improved. If the data holding characteristic of the DRAM is improved, the refresh cycle can be set to be longer. As a result, the power consumption can be reduced. When the manufacturing method of the present invention is applied to a manufacture of a semiconductor device used in a mobile terminal or in a high temperature ambience, the preferable effect may be obtained.

According to the present invention, after the channel doped layer has been formed, and before the sources/drains are formed, substance such as silicon, nitrogen, and germanium is implanted into the source/drain forming region, and the thermal treatment is carried out. As a result, when the channel impurity doped layer is formed, the impurity (boron) introduced in the source/drain forming region is redistributed. As a result of this redistribution, the concentration of the impurity (boron) becomes high in the region corresponding to the edge portions of the gate electrode. As a result, the threshold voltage of the cell transistor can be maintained by a smaller implant dose of boron. Accordingly, the implant dose of the impurity (phosphorus) used to form the sources/drains can be suppressed.

What is claimed is:

1. A method of manufacturing a semiconductor device with a MOS transistor, comprising:
forming a channel impurity doped layer of a first conductive type in a silicon substrate;
implanting first material into regions for diffusion layers of a second conductive type as sources/drains of said MOS transistor in said channel impurity doped layer;
carrying out heat treatment after said implanting process of said first material; and
forming said diffusion layers in said silicon substrate after said carrying out heat treatment.

2. The method according to claim 1, wherein said first material is silicon.

3. The method according to claim 1, wherein said first material is an element of a IV A group.

4. The method according to claim 1, wherein said first material is nitrogen.

5. The method according to claim 1, wherein an implanting energy of said first material is determined such that a range of said first material is smaller than a depth of said diffusion layers from a surface of said silicon substrate.

6. The method according to claim 1, wherein an implant dose of said first material is equal to or more than 1×10¹³ cm⁻² and less than or equal to 1×10¹⁴ cm⁻².

7. The method according to claim 1, wherein said carrying out heat treatment comprises:
carrying out said heat treatment in a range of 800° C. to 1100° C.

8. The method according to claim 1, further comprising:
forming a gate electrode of said MOS transistor through a gate insulating film on said silicon substrate; and
carrying out a thermal oxidizing process after said forming a gate electrode,
said forming a gate electrode and said carrying out a thermal oxidizing process are executed between said forming a channel impurity doped layer and said implanting first material.

9. The method according to claim 1, further comprising:
forming a gate electrode of said MOS transistor through a gate insulating film on said silicon substrate,
said forming a gate electrode is executed between said forming a channel impurity doped layer and said implanting first material, and
said carrying out heat treatment comprises:
carrying out a thermal oxidizing process.

10. The method according to claim 1, further comprising:
forming a capacitor connected with one of said diffusion layers.
